(19) United States
(12) Patent Application Publication
(10) Pub. No.: US 2024/0179927 A1
(43) Pub. Date: May 30, 2024

(54) BIAS TRIGGERED MODE-SWITCHABLE PHOTODETECTOR FROM BROADBAND TO NEAR INFRARED

(71) Applicant: Purdue Research Foundation, West Lafayette, IN (US)

(72) Inventors: Sunghwan Lee, West Lafayette, IN (US); Hyeonghun Kim, West Lafayette, IN (US)

(73) Assignee: Purdue Research Foundation, West Lafayette, IN (US)

(21) Appl. No.: 18/525,313

(22) Filed: Nov. 30, 2023

Related U.S. Application Data
(60) Provisional application No. 63/429,053, filed on Nov. 30, 2022.

(51) Int. Cl. H10K 30/10; H10K 30/84; H10K 39/32; H10K 85/10

(52) U.S. Cl. CPC H10K 30/10; H10K 30/84; H10K 39/32; H10K 85/1135

(57) ABSTRACT

A photodetector diode may have a first electrode and a silicon substrate having an n-type black silicon (b-Si) structure formed thereon. The silicon substrate may be at least partially disposed on the first electrode. A junction layer coating may be applied to the b-Si structure. The photodetector diode may have a second electrode positioned on top of the junction layer. The second electrode being transparent.

### CROSS REFERENCE TO RELATED APPLICATIONS

This application claims the benefit of U.S. Provisional Application No. 63/429,053 filed Nov. 30, 2022, the entirety of which is hereby incorporated by reference.

### BACKGROUND

For decades, Silicon (Si) has been a primary element for the semiconductor industry. The material application is now being expanded to photodetectors owing to its bandgap (1.12 eV) suitable for broadband detection. Conventional Si detectors are often designed to be broadband spectral and need to be equipped with an auxiliary bandpass filter to aim for a specific purpose (e.g., daily light imaging or night vision imaging requiring a NIR-blocking or passing filter, respectively). However, as complementary filters are added, the scope of application of the vision system can become progressively smaller. For example, even if a bare Si device has the potential to be used for night-vision, its functionality is limited to visible-light imaging as soon as the NIR-blocking filter is permanently mounted (i.e., single mode operation for the visible).

### BRIEF DESCRIPTION OF THE DRAWINGS

The embodiments may be better understood with reference to the following drawings and description. The components in the figures are not necessarily to scale. Moreover, in the figures, like-referenced numerals designate corresponding parts throughout the different views.

FIG. 1 illustrates a first example of a photodetector diode.

FIG. 2 illustrates an example of the photodetector at various stages of manufacture.

FIG. 3A-D illustrates various views of an example of a PEDOT coated b-Si.

FIG. 4 illustrates examples of current-voltage curves of a photodetector diode under dark and light illumination.

FIG. 5 illustrates bandgaps of planar-Si and b-Si.

FIG. 6A-B illustrates the behavior of electrons trapped in localized states before and after light injection.

FIG. 7 illustrates time-resolved photocurrent measurement at a 1 Hz of pulse bias (−2 to 2 V).

FIG. 8A-B illustrates spatial photocurrent mapping results.

FIG. 9 illustrates an example of a system having a camera.

FIG. 10 illustrates a second example of the system.

### DETAILED DESCRIPTION

For decades, Silicon (Si) has been a primary element for the semiconductor industry. The material application is now being expanded to photodetectors owing to its bandgap (1.12 eV) suitable for broadband detection. An early version of Si-based photodetectors has been fabricated in the form of p-n or p-i-n diodes vertically stacked on a flat wafer. Due to the insufficient light collection capability of these early photodetectors, an anti-reflective coated glass, having multiple dielectrics, needed to be used as a substrate which causes process complexities and a surge in unit price. To address such limitation, chemical and physical etching processes that induce nanostructured surfaces have been proposed as the most promising alternatives to boost the light-collection efficiency without an aid of the supplementary glass. The nanostructure surface of Si, refined from a flat shape to a vertically aligned nanostructure, instrumentally enhances light collection as a “self” anti-reflector. Such a nanostructure uniquely forms a continuous decrease in the refractive index from the bulk Si to air and, consequently, the wafer achieves a dramatically depressed reflectance (<10%). This approach has been extensively utilized with the term ‘black silicon (b-Si)’ as an essential building block for a wide range of optoelectronic devices such as solar cells and photodetectors.

The increment of the surface area during the etching process inevitably causes unexpected issues called “surface recombination”. Photo-induced electron-hole pairs are readily recombined at surface defects, critically limiting efficient charge extraction. In this respect, to advance the b-Si photodetectors, it is essential to secure a passivation layer or charge transport layer to stabilize the surface defects or reinforce a charge separation capability through a built-in potential, while maintaining process simplicity. In particular, a passivation oxide layer, atomic layer deposited (ALD) Al2O3, has already contributed to the fabrication of high-performance solar cells with an efficiency of above 22%. However, the strategy based on the highly resistive insulating layer limited the device configuration to the form of a back-contact-back-junction which is not favorable for the fabrication of multi-pixel sensors (e.g., image sensors). Alternatively, inorganic charge transport layers (e.g., SixNy or a-Si:H) have been employed to construct a vertical-type device while depressing the surface recombination. However, they require a sophisticated and time-consuming process accompanied by a high thermal budget to form a uniform layer on the b-Si wafer. Moreover, the high refractive index of the inorganic layers (e.g., 3.5-4.5 for a-Si:H), suppressing the anti-reflective effect, provokes an additional issue due to an undesirable increment of the reflectance.

Conductive polymers, such as poly(3,4-ethylene dioxythiophene) (PEDOT) and its derivatives, are promising alternatives for the transport layers due to their low refractive index (1.2-1.6) close to air. Furthermore, their relatively affordable and straightforward process is another key benefit for making the materials attractive compared to other inorganic counterparts. However, the relatively low charge mobility, inefficient charge extraction capability from the Si, and poor step-coverage of conventional solution-processed polymers remain unresolved.

Conventional Si detectors are designed to be broadband spectral and need to be equipped with an auxiliary bandpass filter to aim for a specific purpose (e.g., daily light imaging or night vision imaging requiring a NIR-blocking or passing filter, respectively). However, as complementary filters are added, the scope of application of the vision system can become progressively smaller. For example, even if a bare Si device has the potential to be used for night-vision, its functionality is limited to visible-light imaging as soon as the NIR-blocking filter is permanently mounted (i.e., single mode operation for the visible). Therefore, a breakthrough approach to a more functional and broadly applicable vision system is provided to maximize the value of Si-photodetectors.

Oxidative chemical vapor deposition (oCVD) is a recently emerged technique for gas-phase synthesis of a polymer film. As well as the superior electrical property of oCVD-based polymers, distinctly notable step coverage of the gas-phase deposition, compared to conventional solution-based coating methods, have been highlighted in a wide range of research fields such as a lithium-ion battery and light-emitting diodes. Herein, for the first time, we hybridize the oCVD technology and the b-Si wafer approach to realize a high-performance Si photodetector that demonstrates the responsivity of 1.14 A W-1 and detectivity of 1.37×10¹³ Jones. The oCVD process enables conformal coating of highly conductive PEDOT (3,000 S cm-1) on the rough and porous surface of b-Si so that the surface recombination is effectively inhibited while facilitating the charge transport. As a result, the synergistic effect realizes the superior peak detectivity, which is three and seven times higher than that of a conventional PEDOT:PSS-covered b-Si and planar-Si detectors, respectively. Furthermore, we suggest a novel photodetector that operates in unique dual-function modes. By tuning the applied bias, the device functionality is reversibly switched from a broad-band detection mode to a visible-blinded near-infrared (NIR) detecting mode. To the best of our knowledge, this is the first demonstration representing a multi-functional Si photodetector, paving the way for developing an unprecedented and practical vision system for night vision, motion tracking, and bio-sensing.

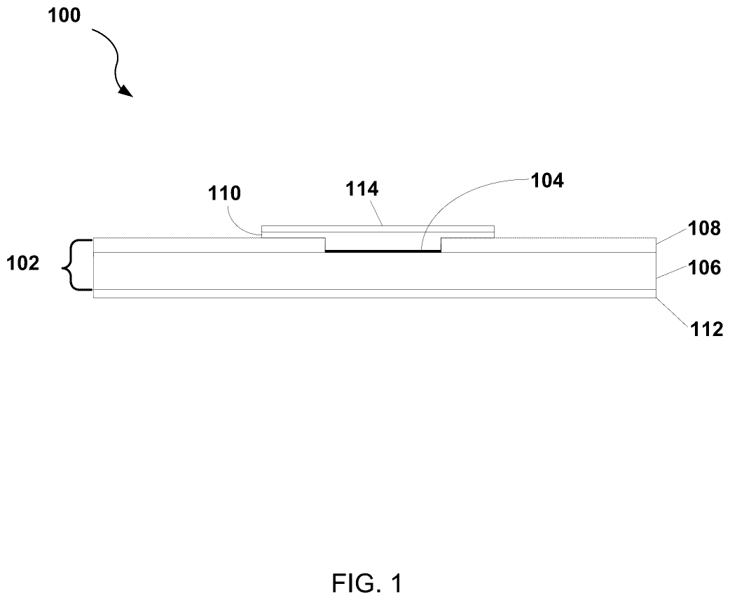

FIG. 1 illustrates a first example of a photodetector diode. The photodetector diode may include a silicon substrate 102 having an n-type black silicon (b-Si) structure 104 formed thereon. The silicon substrate 102 may be an oxidized Si wafer (SiO2/Si). Thus, as illustrated in the example shown in FIG. 1, the silicon substrate may include a silicon layer 106 and an oxide layer 108. In various examples, the oxide layer 108 may be around 100 nm-thick, although thicker or thinner oxide layers are permissible depending on the design.

A portion of the oxide layer of the photodetector diode may be removed by, opening a Si surface, which then may be converted into b-Si through, for example, metal assistant chemical etching. Accordingly, the silicon wafer may have an active area which includes the exposed oxide layer and the b-Structure formed on the silicon layer.

The b-Si structure 104 may be for a porous surface. The porous surface may include macropores and mesopores. Macro-pores refers to pores large enough to be conformally coated by the oCVD technique. Macropores refers to pore diameter sizes bigger than ˜50 nm. For the purposes of clarity and boundary, the upper diameter for a macro pore may reach up to 500 nm. Mesopores refers to pores with diameters which are too small to be conformally coated by oCVD technique, which would be approximately 50 nm or less. For the purposes of clarity and boundary, mesopores, in practice, may be as small as 1 nm. In some examples, the pore depth of both pores may be adjusted deeper than 2 μm.

The optical reflectance of the b-Si structure 104 may be than less than 10% at 400-1,000 nm. This means the reflectance is less than 10%, which is measured by a spectrometer.

The photodetector diode may include a junction layer 110 applied to the Si layer 104 and, more specifically, the b-Si structure 102. The junction layer may include a conjugated polymer. The junction layer 110 may form a Schottky junction with the n-type b-Si structure. For example, the junction layer may include Poly(3,4-ethylenedioxythiophene (PEDOT) film applied using oCVD. The PEDOT may conformally coat the nano-structured b-Si structure. In various experimentation, the approach provided a conductivity of 3,000 S cm⁻¹. The junction layer may be transparent under visible and NIR light. The junction layer may have a refractive index close to air. For example, the junction layer may have a refractive index of 1.2-1.6.

The photodetector may further include a first electrode 112 which receives the silicon layer 106. The first electrode may include, for example, aluminum.

The photodetector may include second electrode 114 positioned on top of the junction layer 110. In some examples, the second electrode 114 may include ITO/MoO₃.

In some examples, the photodetector may reversibly switch between a broad-band detection mode and a visible-blinded near-infrared detecting mode in response to adjusting a biasing voltage applied to the electrodes. The photodetector may provide a first current corresponding to both the near infrared light and a visible light while in broad band detection mode. The photodetector may provide a second current corresponding to near infrared light but not visible light while in NIR detecting mode. As described herein, the wavelength of the visible light may have a wavelength between 400 nm to 800 nm, and the wavelength of the near infared light may have a wavelength between 800 nm and 2300 nm.

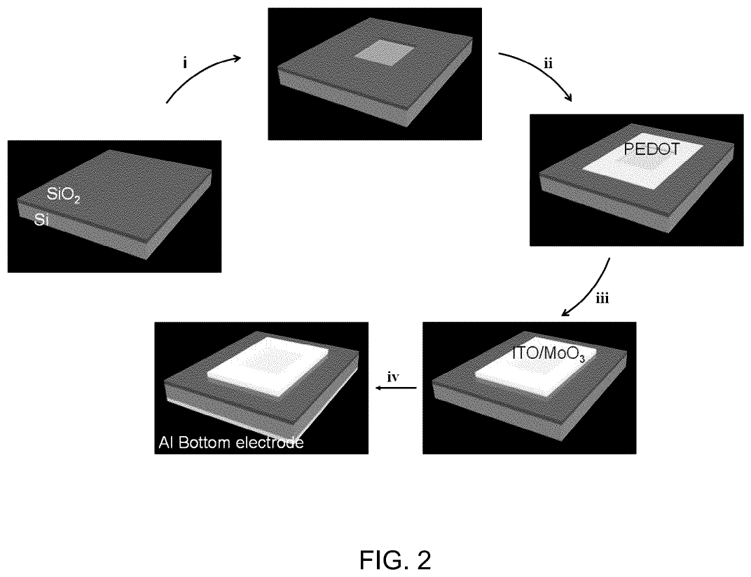

FIG. 2 illustrates an example of the photodetector at various stages of manufacture. A pre-cleaned oxidized Si wafer (SiO2/Si) may be patterned using, for example, photolithography to define the active area. The exposed oxide layer may be wet-etched using a buffered oxide etchant. The opened Si surface may be converted to the b-Si through the metal-assisted-chemical etching (MACE) process (step i).

A PEDOT film was created on the exposed Si layer using oCVD (step ii). The bilayer top electrode, ITO/MoO3 may be deposited using a magnetron sputtering process and thermal evaporation. The Al bottom (step iv) electrode may be deposited using thermal evaporation.

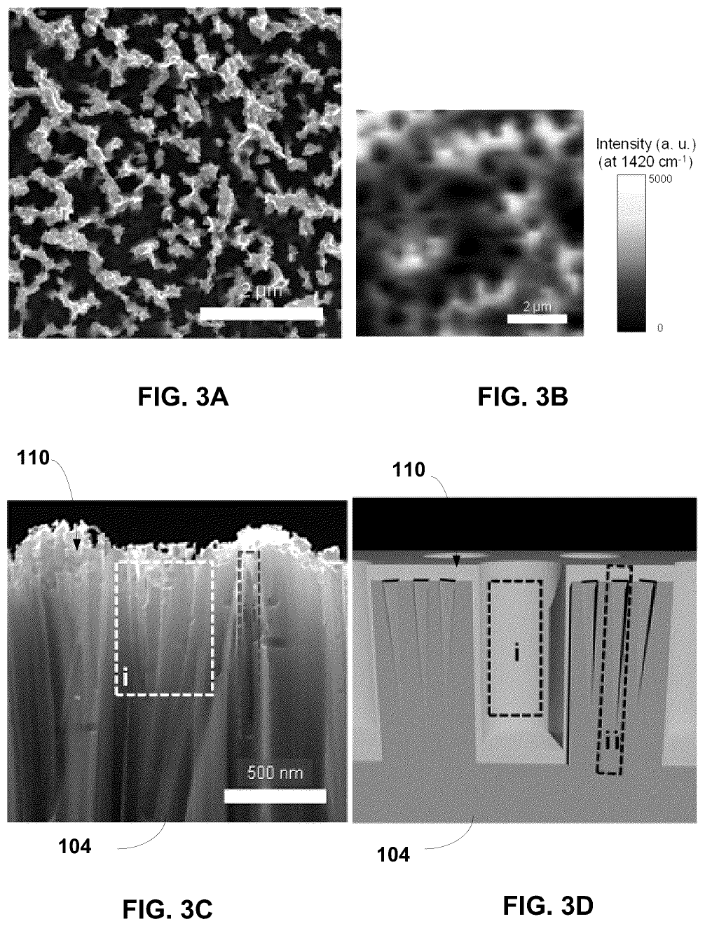

FIG. 3A-D illustrates various views of an example of the PEDOT coated b-Si. FIG. 3A is a cross-top-view SEM images of the PEDOT-coated b-Si. FIG. 3B is a Raman mapping image of the PEDOT-coated b-Si. FIG. 3C is a cross-sectional SEM image. FIG. 3D is a schematic, representing the pores of the b-Si.

As illustrated in FIGS. 3C and 3D, the black silicon (b-Si) structure 104 includes macropores (i) and mesopores (ii). The junction layer 110, includes the oCVD PEDOT-coating in this example, may conformally coat the macropores 110.

Due to the larger hole/pore diameter for macropores, deeper regions of the macro pores are conformally coated. The macropore may retain an open entrance even after the coating. For the mesopores, due to the smaller diameter of the hole/pores, the deeper regions may not be conformally coated and the entrance would be blocked. The interior regions of the mesopores may remain substantially uncoated but the entrance to the mesopore may be covered.

In other words, the b-Si substrate structure may have pores of various sizes The coating may conformally coats a surface a first portion of the pores, leaving an opening (entrance) of the first portion of the pores. However, the coating may cover the opening of a second portion of the pores, leaving an interior surface of the second portion of the pores uncoated.

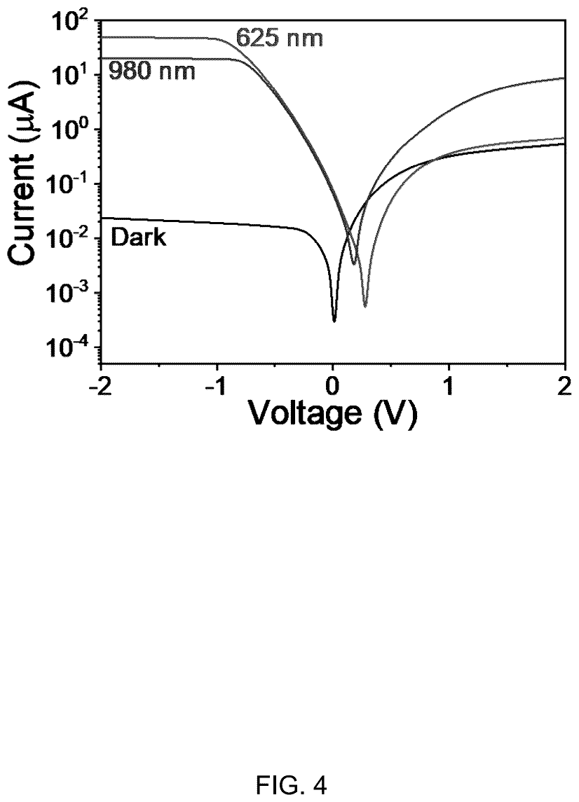

FIG. 4 illustrates examples of current-voltage curves of the photodetector diode under dark and light illumination (625 nm and 980 nm with an irradiance of 1 mW cm-2). The reverse bias (negative voltage) triggered photocurrent generation under both lights, while the opposite (forward bias) voltage condition made the device to NIR-selective detector. Accordingly, by tuning the applied bias to the photodetector, the device functionality is reversibly switched from a broad-band detection mode to a visible-blinded near-infrared (NIR) detecting mode.

The photodetection behavior of the PEDOT/b-Si diodes is related to two discriminated light absorption mechanisms; one is attributed to the excitation from the valance-to-conduction band (VTC), and the other is relevant to the localized state-to-conduction band (LTC) transition.

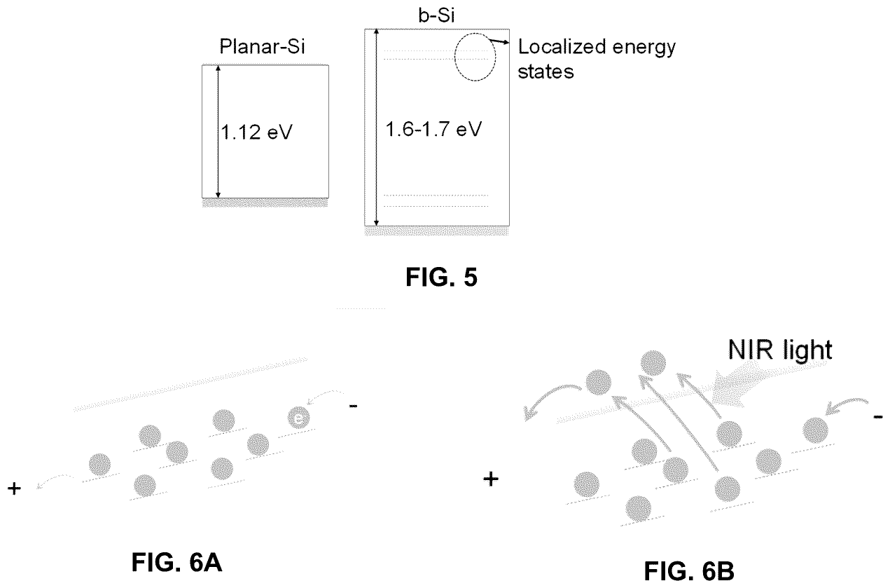

A typical photo-detection behavior is related to the valence-to-conduction band (VTC) transition. A photon with an energy above a bandgap excites an electron from a valence band to a conduction band and leaves behind a hole in the valence band. The Schottky junction between the oCVD PEDOT/Si interface separates the generated electron-hole pairs and makes a photocurrent. FIG. 5 illustrates bandgaps of planar-Si and b-Si. The MACE-derived b-Si has a broader bandgap (1.6-1.7 eV, the right image of FIG. 5) than that of the standard planar-Si (1.12 eV, the left image of FIG. 5) due to a quantum confinement effect. The bandgap of the b-Si corresponds to light photon energy with a 730-780 nm wavelength, which is a boundary between visible and NIR light. Therefore, only the visible light with sufficient energy to trigger the VTC transition is detectable at the porous region, in this case, the PEDOT/b-Si interface. Contrarily, the NIR light cannot be absorbed effectively based on the way and be collected only in the bulk silicon (low bandgap region) underneath the b-Si layer. Besides, the VTC-assisted photo-detection mainly occurs at a reverse bias owing to the Schottky barrier between the PEDOT/b-Si. For these reasons, the device is relatively more sensitive to visible light under reverse bias.

The other working mechanism is based on a localized state-to-conduction-to-conduction band (LTC) transition. A wide range of research, constructing a Si nanowire detector based on the MACE method, demonstrated that photo-detection in the Si nanostructure could be realized by localized energy states. FIG. 6A-B illustrates the behavior of electrons trapped in localized states before and after light injection. Electrons are trapped in the localized states under dark conditions at a non-zero bias. The trapped electrons readily jump to the conduction band under a light injection and the external bias continually charges the empty localized states. The excited electrons flow into the (+)-electrode, while new electrons are filled up from the (−) electrode to maintain overall neutrality. With the complete electron flow, a photocurrent can be measured. Notably, the LTC-assisted detection is available regardless of the bias polarity of a diode, contrary to the VTC mechanism highly depending on the depletion region in the backward bias. Moreover, the narrow energy difference between the conduction band and localized energy states enables the absorption of NIR light.

The most significant difference between the VTC and LTC mechanisms lies in the location where these phenomena occur. VTC occurs around the PEDOT/Si interface because it requires a built-in potential, while LTC is more likely to occur in regions where only b-Si is present without a junction. Visible light has a high absorption rate in the b-Si, so most of the light is absorbed around the PEDOT/b-Si junction. However, NIR light can penetrate deeper due to its low absorption coefficient in the b-Si. Consequently, visible light is detectable based on the VTC mechanism, while NIR light detection is attributed to the LTC mechanism. The high visible light selectivity recorded under reverse bias and the NIR detection selectivity observed under forward bias coincide with these characteristics.

The non-covered surface defects, stimulating recombination of the electron-hole pairs, are not favorable for VTC-based light detection and may decrease detection capability at the backward bias. In contrast, the defect sites create abundant localized energy states and facilitate the LTC mechanism. In other words, there is a tradeoff between the high-performance detection at the backward bias and the selective NIR detection at the forward bias. In this respect, the oCVD process, covering macropores while preserving the mesopores to be uncoated, is notably advantageous for optimizing both properties simultaneously by controlling surface defect densities.

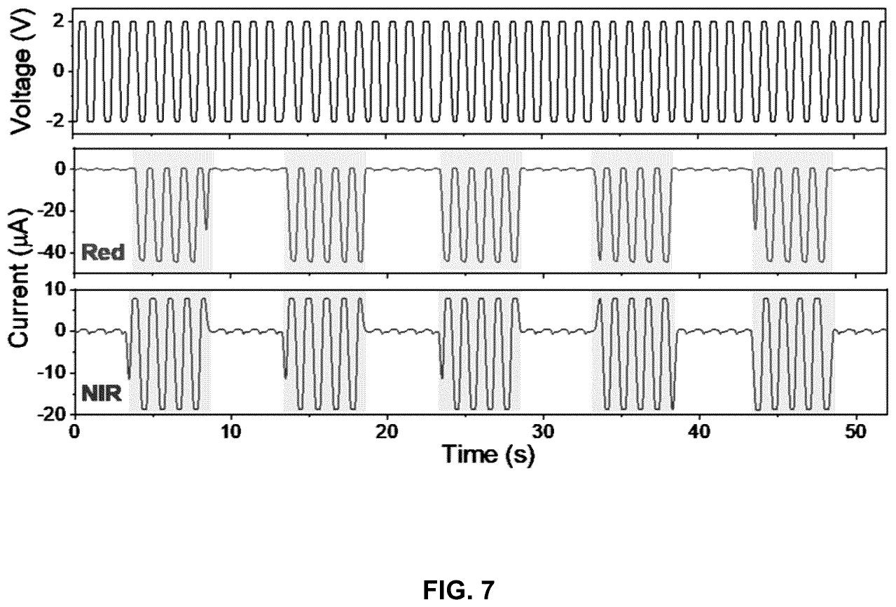

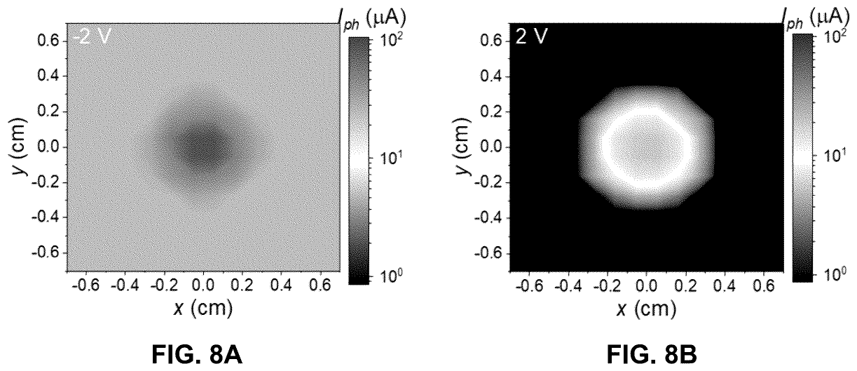

FIG. 7 illustrates time-resolved photocurrent measurement at a 1 Hz of pulse bias (−2 to 2 V). In various experimentation, the diode may be included in a photo-detecting system using a pulsed voltage (−2 V to 2 V). Under the red-light illumination (625 nm), the photocurrent was generated only at the negative voltage, whereas the NIR light (980 nm) triggers the photocurrent at both bias polarities. FIG. 8A-B illustrates spatial photocurrent mapping results. The photocurrent of the diode was measured under an artificial light illumination consisting of diffused white LED (6,000 K cool white) and centralized NIR light. The maps represent the photocurrent recorded at −2 V (FIG. 8A) and 2 V (FIG. 8B), respectively. The system was able to selectively extract NIR information from a broad-band spectral illumination composed of both visible and NIR lights. The maximal detectivity was above 10¹³ Jones at a low bias of 2 V. The rise/decay times were around 100 μs.

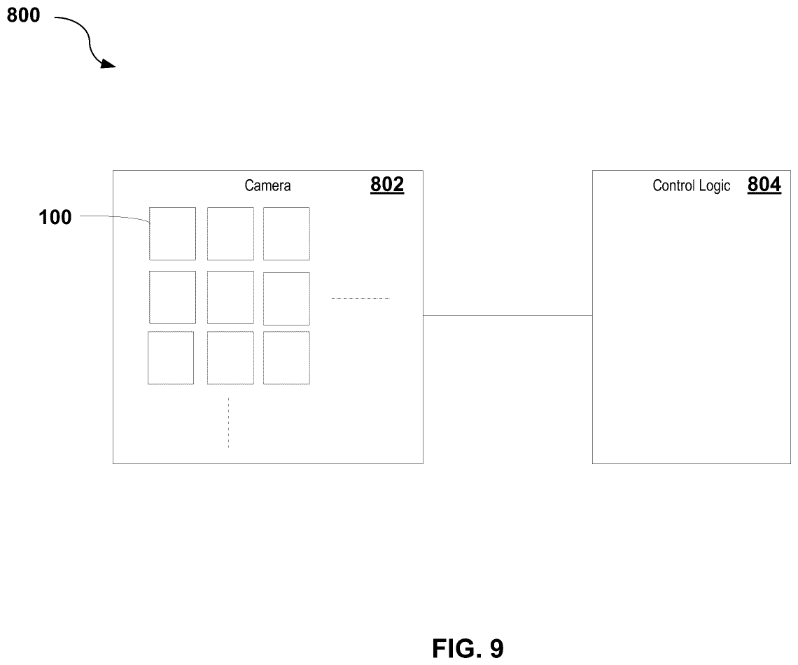

FIG. 9 illustrates an example of a system 800 having a camera 802. The camera 802 may include a plurality of photodetector diodes 100. The photodetector diodes 100 may reversibly switch from a broad-band detection mode to a visible-blinded near-infrared (NIR) detecting mode in response to adjusting a biasing voltage applied to the electrodes of the diodes, as described herein.

The photodetector diodes may each provide an electrical signal corresponding to a measure of near infrared light and a visible light while in broad-band detection mode. The photodetector diodes may also provide electrical signal corresponding to a measure of near infrared light but not visible light while in NIR detecting mode.

In some examples, the system may include control logic 804. The control logic may cause a signal to be sent to the camera to switch between visible-blinded NIR detecting mode and broad-band detection mode. In various embodiments, the system may include mobile device where a user can interactively select the visible-blinded NIR detecting mode and broad-band detection mode. It should be appreciated that in other examples, the control logic 804 may be included with the camera 802.

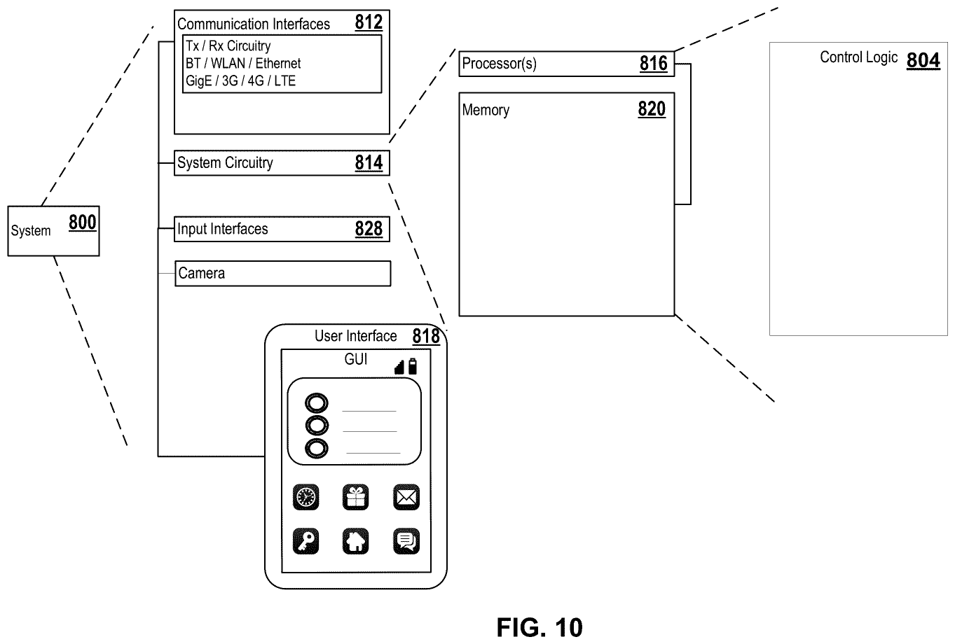

FIG. 10 illustrates a second example of the system. The system may include communication interfaces 812, input interfaces 828 and/or system circuitry 814. The system circuitry 814 may include a processor 816 or multiple processors. Alternatively or in addition, the system circuitry 814 may include memory 820.

The processor 816 may be in communication with the memory 820. In some examples, the processor 816 may also be in communication with additional elements, such as the camera, the communication interfaces 812, the input interfaces 828, and/or the user interface 818. Examples of the processor 816 may include a general processor, a central processing unit, logical CPUs/arrays, a microcontroller, a server, an application specific integrated circuit (ASIC), a digital signal processor, a field programmable gate array (FPGA), and/or a digital circuit, analog circuit, or some combination thereof.

The processor 816 may be one or more devices operable to execute logic. The logic may include computer executable instructions or computer code stored in the memory 820 or in other memory that when executed by the processor 816, cause the processor 816 to perform the operations the control logic 804 and/or the system 800. The computer code may include instructions executable with the processor 816.

The memory 820 may be any device for storing and retrieving data or any combination thereof. The memory 820 may include non-volatile and/or volatile memory, such as a random access memory (RAM), a read-only memory (ROM), an erasable programmable read-only memory (EPROM), or flash memory. Alternatively or in addition, the memory 820 may include an optical, magnetic (hard-drive), solid-state drive or any other form of data storage device. The memory 820 may include at least one of the control logic 804 and/or the system 800. Alternatively or in addition, the memory may include any other component or sub-component of the system described herein.

The user interface 818 may include any interface for displaying graphical information. The system circuitry 814 and/or the communications interface(s) 812 may communicate signals or commands to the user interface 818 that cause the user interface to display graphical information. Alternatively or in addition, the user interface 818 may be remote to the system and the system circuitry 814 and/or communication interface(s) may communicate instructions, such as HTML, to the user interface to cause the user interface to display, compile, and/or render information content. In some examples, the content displayed by the user interface 818 may be interactive or responsive to user input. For example, the user interface 818 may communicate signals, messages, and/or information back to the communications interface 812 or system circuitry 814.

The system may be implemented in many different ways. In some examples, the system may be implemented with one or more logical components. For example, the logical components of the system may be hardware or a combination of hardware and software. The logical components may include the control logic, or any component or subcomponent of the system. In some examples, each logic component may include an application specific integrated circuit (ASIC), a Field Programmable Gate Array (FPGA), a digital logic circuit, an analog circuit, a combination of discrete circuits, gates, or any other type of hardware or combination thereof. Alternatively or in addition, each component may include memory hardware, such as a portion of the memory 820, for example, that comprises instructions executable with the processor 816 or other processor to implement one or more of the features of the logical components. When any one of the logical components includes the portion of the memory that comprises instructions executable with the processor 816, the component may or may not include the processor 816. In some examples, each logical component may just be the portion of the memory 820 or other physical memory that comprises instructions executable with the processor 816, or other processor(s), to implement the features of the corresponding component without the component including any other hardware. Because each component includes at least some hardware even when the included hardware comprises software, each component may be interchangeably referred to as a hardware component.

Some features are shown stored in a computer readable storage medium (for example, as logic implemented as computer executable instructions or as data structures in memory). All or part of the system and its logic and data structures may be stored on, distributed across, or read from one or more types of computer readable storage media. Examples of the computer readable storage medium may include a hard disk, a flash drive, a cache, volatile memory, non-volatile memory, RAM, flash memory, or any other type of computer readable storage medium or storage media. The computer readable storage medium may include any type of non-transitory computer readable medium, such as a CD-ROM, a volatile memory, a non-volatile memory, ROM, RAM, or any other suitable storage device.

The processing capability of the system may be distributed among multiple entities, such as among multiple processors and memories, optionally including multiple distributed processing systems. Parameters, databases, and other data structures may be separately stored and managed, may be incorporated into a single memory or database, may be logically and physically organized in many different ways, and may implemented with different types of data structures such as linked lists, hash tables, or implicit storage mechanisms. Logic, such as programs or circuitry, may be combined or split among multiple programs, distributed across several memories and processors, and may be implemented in a library, such as a shared library (for example, a dynamic link library (DLL).

All of the discussion, regardless of the particular implementation described, is illustrative in nature, rather than limiting. For example, although selected aspects, features, or components of the implementations are depicted as being stored in memory(s), all or part of the system or systems may be stored on, distributed across, or read from other computer readable storage media, for example, secondary storage devices such as hard disks, network drives, flash memory drives, etc. Moreover, the various logical units, circuitry and screen display functionality is but one example of such functionality and any other configurations encompassing similar functionality are possible.

The respective logic, software or instructions for implementing the processes, methods and/or techniques discussed above may be provided on computer readable storage media. The functions, acts or tasks illustrated in the figures or described herein may be executed in response to one or more sets of logic or instructions stored in or on computer readable media. The functions, acts or tasks are independent of the particular type of instructions set, storage media, processor or processing strategy and may be performed by software, hardware, integrated circuits, firmware, micro code and the like, operating alone or in combination. Likewise, processing strategies may include multiprocessing, multitasking, parallel processing and the like. In one example, the instructions are stored on a removable media device for reading by local or remote systems. In other examples, the logic or instructions are stored in a remote location for transfer through a computer network or over telephone lines. In yet other examples, the logic or instructions are stored within a given computer and/or central processing unit (“CPU”).

Furthermore, although specific components are described above, methods, systems, and articles of manufacture described herein may include additional, fewer, or different components. For example, a processor may be implemented as a microprocessor, microcontroller, application specific integrated circuit (ASIC), discrete logic, or a combination of other type of circuits or logic. Similarly, memories may be DRAM, SRAM, Flash or any other type of memory. Flags, data, databases, tables, entities, and other data structures may be separately stored and managed, may be incorporated into a single memory or database, may be distributed, or may be logically and physically organized in many different ways. The components may operate independently or be part of a same apparatus executing a same program or different programs. The components may be resident on separate hardware, such as separate removable circuit boards, or share common hardware, such as a same memory and processor for implementing instructions from the memory. Programs may be parts of a single program, separate programs, or distributed across several memories and processors.

A second action may be said to be “in response to” a first action independent of whether the second action results directly or indirectly from the first action. The second action may occur at a substantially later time than the first action and still be in response to the first action. Similarly, the second action may be said to be in response to the first action even if intervening actions take place between the first action and the second action, and even if one or more of the intervening actions directly cause the second action to be performed. For example, a second action may be in response to a first action if the first action sets a flag and a third action later initiates the second action whenever the flag is set.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed.

What is claimed is:

1. A photodetector diode comprising:
a first electrode;
a silicon substrate having an n-type black silicon (b-Si) structure formed thereon, the silicon substrate being at least partially disposed on the first electrode;
a junction layer coating applied to the b-Si structure; and
a second electrode positioned on top of the junction layer, the second electrode being transparent.

2. The photodetector diode of claim 1, wherein
the photodetector reversibly switches from a broad-band detection mode to a visible-blinded near-infrared (NIR) detecting mode in response to adjusting a biasing voltage applied to the electrodes.

3. The photodetector of claim 2, wherein the photodetector provides current corresponding to near infrared light and a visible light while in broad-band detection mode,
wherein the photodetector provides current corresponding to near infrared light but not visible light while in NIR detecting mode.

4. The photodetector of claim 3, wherein the wavelength of the visible light has a wavelength between 400 nm to 800 nm, wherein the wavelength of the near infrared light has a wavelength between 800 nm and 2300 nm.

5. The apparatus of claim 1, wherein the b-Si structure is porous.

6. The apparatus of claim 1, wherein the b-Si substrate structure comprises pores various sizes, wherein the junction layer coating conformally coats a surface a first portion of the pores, wherein the junction layer coating covers the opening of a second portion of the pores, leaving a surface of the second portion of the pores uncoated.

7. The apparatus of claim 1, wherein the b-Si substrate structure comprises macropores and mesopores, wherein the macropores have diameters greater than 50 nm, wherein the mesopores have diameters are less than 50 nm.

8. The apparatus of claim 7, wherein the pore depth is greater than 2 μm.

9. The apparatus of claim 1, wherein the optical reflectance of the b-Si substrate layer is than less than 10% at 400-1,000 nm

10. The apparatus of claim 1, wherein the junction layer forms a Schottky junction with the n-type b-Si layer.

11. The apparatus of claim 1, wherein the junction layer is transparent under visible and near infrared (NIR) light.

12. The apparatus of claim 1, wherein the junction layer has a refractive index of 1.2-1.6.

13. The apparatus of claim 1, wherein the junction layer comprises a conjugated polymer.

14. The apparatus of claim 1, wherein the conjugated polymer is Poly(3,4-ethylenedioxythiophene, PEDOT.

15. The apparatus of claim 14, wherein the PEDOT is synthesized by an oxidative chemical vapor deposition process (oCVD) such that the PEDOT is conformally coated to the nanostructured b-Si layer

16. The apparatus of claim 1, wherein the second electrode comprises ITO/MoO₃.

17. The apparatus of claim 1, wherein the first electrode comprises aluminum.

18. A camera, comprising:
a plurality of photodetector diodes, the photodetector diodes configured to reversibly switches from a broad-band detection mode to a visible-blinded near-infrared (NIR) detecting mode in response to adjusting a biasing voltage applied to the electrodes,
wherein the photodetector diode provides an electrical signal corresponding to a measure of near infrared light and a visible light while in broad-band detection mode,
wherein the photodetector provides current corresponding to a measure of near infrared light but not visible light while in NIR detecting mode.

19. The camera of claim 1, wherein the photodetector diodes receive a control signal to switch between visible-blinded NIR detecting mode and broad-band detection mode.

20. A method of making a photodetector diode, comprising:
converting an area of a silicon wafer to b-Si;
depositing Poly(3,4-ethylenedioxythiophene) (PEDOT) onto the area using oxidative chemical vapor deposition (oCVD);
applying a top electrode on top of the deposited PEDOT; and
applying a bottom electrode underneath the silicon wafer.

21. The method of claim 20, further comprising:
defining the area on a silicon wafer using photolithography, and
wet etching the exposed area using a buffered oxide etchant.

22. The method of claim 20, wherein the top electrode is transparent.

23. The method of claim 20, wherein the top electrode comprises ITO/MoO₃

24. The method of claim 20, wherein the bottom electrode comprises aluminum.

25. The method of claim 20, wherein the silicon wafer comprises SiO₂/Si.
